(19) United States
(12) Patent Application Publication
(10) Pub. No.: US 2025/0102373 A1
(43) Pub. Date: Mar. 27, 2025

(54) TEMPERATURE MEASUREMENT ASSEMBLY, SUBSTRATE PROCESSING APPARATUS, METHOD OF PROCESSING SUBSTRATE, AND METHOD OF MANUFACTURING SEMICONDUCTOR DEVICE

(71) Applicant: Kokusai Electric Corporation, Tokyo (JP)

(72) Inventor: Tokunobu AKAO, Toyama-shi (JP)

(73) Assignee: Kokusai Electric Corporation, Tokyo (JP)

(21) Appl. No.: 18/772,725

(22) Filed: Jul. 15, 2024

(30) Foreign Application Priority Data
Sep. 21, 2023 (JP) 2023-155812

(51) Int. Cl. G01K 13/024; G01K 1/02; G01K 1/08; G01K 1/14; H01L 21/67

(52) U.S. Cl. CPC G01K 13/024; G01K 1/026; G01K 1/08; G01K 1/14; H01L 21/67248

(57) ABSTRACT

There is provided a technique that includes: a gas supply pipe including therein a flow path through which a gas flows; at least one temperature sensor including a temperature measurement gauge disposed outside the gas supply pipe; and a protective tube inside which the gas supply pipe and the at least one temperature sensor are disposed, wherein an outlet of the gas supply pipe configured to eject the gas into the protective tube is positioned higher than the at least one temperature sensor, and the gas descends via a gap between an outer wall of the at least one temperature sensor and an inner wall of the protective tube.

### CROSS-REFERENCE TO RELATED APPLICATION

This application is based upon and claims the benefit of priority from Japanese Patent Application No. 2023-155812, filed on Sep. 21, 2023, the entire contents of which are incorporated herein by reference.

### TECHNICAL FIELD

The present disclosure relates to a temperature measurement assembly, a substrate processing apparatus, a method of processing a substrate, and a method of manufacturing a semiconductor device.

### BACKGROUND

In a method of manufacturing a semiconductor device, there are cases where a vertical substrate processing apparatus is used as an apparatus configured to form an oxide film or a metal film on a substrate (hereinafter referred to as “wafer”). When generating a predetermined film on the wafer, the interior of a process chamber is heated to a predetermined temperature while supplying a process gas to the interior of the process chamber. To maintain the interior of the process chamber at the predetermined temperature, a temperature sensor configured to detect the temperature, such as a thermocouple, is installed in the interior of the process chamber.

An example of thermocouples that are usable under a high-temperature environment is a tungsten-rhenium (WRe) sheathed thermocouple. The WRe thermocouple may be used at high temperatures but may not be used in an oxidizing atmosphere. The sheathed thermocouple is configured such that a thermocouple and an insulator are inserted into a metal sheath tube, the interior of the sheath tube is filled with an inert gas, and a sealing end of the sheath tube is sealed, thereby isolating the thermocouple from an oxidizing atmosphere.

However, under a high-temperature environment, substances that deteriorate the sheath tube, such as oxygen, are generated from materials constituting the process chamber or deposited films. In a case where the sheath tube deteriorates, the substances such as oxygen may reach the interior of the sheath tube. As a result, a state in which the inside of the sheath tube is completely filled with an inert atmosphere is destroyed, leading to deterioration of the thermocouple. This may cause a decrease in an electromotive force of the thermocouple, or even disconnection of the thermocouple, resulting in inaccurate temperature measurement. In particular, in a case where the sheath tube is covered with a protective tube, there is a possibility of long-term exposure to released gases from the protective tube that were trapped inside the protective tube. Further, evaporation or gas emission from the sheath tube itself may lead to deterioration of the protective tube or contamination of the process chamber.

### SUMMARY

Some embodiments of the present disclosure provide a technique that is capable of enabling stable temperature measurement for a long period under a high-temperature environment.

According to some embodiments of the present disclosure, there is provided a technique that includes: a gas supply pipe including therein a flow path through which a gas flows; at least one temperature sensor including a temperature measurement gauge disposed outside the gas supply pipe; and a protective tube inside which the gas supply pipe and the at least one temperature sensor are disposed, wherein an outlet of the gas supply pipe configured to eject the gas into the protective tube is positioned higher than the at least one temperature sensor, and the gas descends via a gap between an outer wall of the at least one temperature sensor and an inner wall of the protective tube.

### BRIEF DESCRIPTION OF DRAWINGS

The accompanying drawings, which are incorporated in and constitute a part of the specification, illustrate embodiments of the present disclosure.

FIG. 1 is a longitudinal cross-sectional view illustrating an example of a process furnace according to some embodiments of the present disclosure.

FIG. 2 is a longitudinal cross-sectional view illustrating a temperature measurement assembly according to some embodiments of the present disclosure.

FIG. 3 is an enlarged longitudinal cross-sectional view of main components illustrating a temperature measurement assembly according to some embodiments of the present disclosure and a vicinity of an installation region thereof.

FIG. 4 is an enlarged longitudinal cross-sectional view of main components illustrating a tip of a temperature measurement assembly according to some embodiments of the present disclosure.

FIG. 5 is a flowchart illustrating a method of processing a substrate according to some embodiments of the present disclosure.

FIG. 6A is a longitudinal cross-sectional view illustrating a modification of a temperature measurement assembly according to some embodiments of the present disclosure, and FIG. 6B is a bottom surface view of FIG. 6A.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

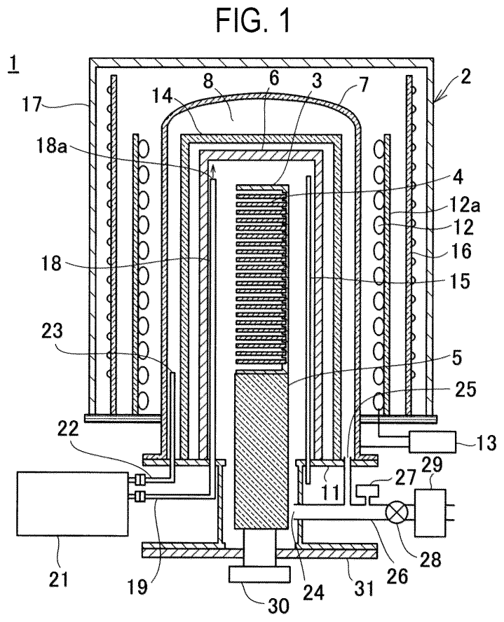

Hereinafter, some embodiments of the present disclosure will be described mainly with reference to FIGS. 1 to 5. In addition, the drawings used in the following description are schematic, and dimensional relationships, ratios, and the like of respective components illustrated in the drawings may not match actual ones. Further, dimensional relationships, ratios, and the like of various components among plural drawings may not match one another.

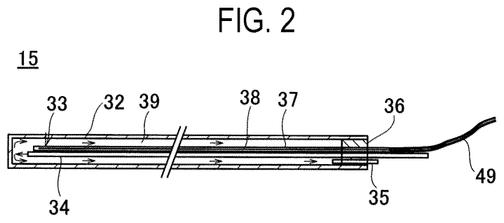

First, in FIG. 1, some embodiments according to the present disclosure will be described. FIG. 1 illustrates a longitudinal cross-sectional view of a process furnace 2 in a substrate processing apparatus 1 according to the embodiments of the present disclosure. In addition, FIGS. 2 to 4 illustrate the same configuration as the substrate processing apparatus 1 illustrated in FIG. 1, and the same reference numerals are given to components substantially the same as those described in FIG. 1 and descriptions thereof are omitted.

In addition, the substrate processing apparatus 1 according to the embodiments is constituted as a so-called batch-type vertical SiC annealing apparatus configured to anneal a plurality of SiC substrates aligned in the vertical direction. By constituting the substrate processing apparatus 1 as a batch-type processing apparatus, it is possible process a great number of substrates to be processed at once, resulting in improved productivity.

The substrate processing apparatus 1 is formed with, for example, the same configuration as disclosed in the related art. The substrate processing apparatus 1 includes the process furnace 2, and a boat 3 serving as a substrate holder is removably inserted into the process furnace 2. The boat 3 is made of, for example, a heat-resistant material such as carbon graphite or SiC. The boat 3 is configured to hold a plurality of wafers 4, which serve as substrates made of SiC or other materials, in such a state that the wafers 4 are arranged in a horizontal posture and stacked along a vertical direction with centers of the wafers 4 aligned with one another. In addition, a boat insulator 5, which serves as a thermal insulator made of, for example, a heat-resistant material such as quartz or SiC, is arranged at a lower side of the boat 3. The boat insulator 5 is configured to support the boat 3 from below, making it difficult for heat from an induction target 6, which is described below, to be transferred downward of the process furnace 2. When the boat 3 charged with the plurality of wafers 4 is loaded into the process furnace 2, heat treatment is performed.

Next, a configuration of the process furnace 2 included in the substrate processing apparatus 1 will be described.

As illustrated in FIG. 1, the process furnace 2 includes a reaction tube 7, which is made of a heat-resistant material such as quartz or SiC and is formed in a cylindrical shape with a closed upper end and an open lower end. A reaction chamber 8 serving as a process chamber is formed in a cylindrical hollow space of the reaction tube 7. The reaction chamber 8 is configured to accommodate therein the above-described boat 3, which holds the wafers 4 serving as substrates made of SiC or other materials.

A manifold 11 is disposed concentrically with and below the reaction tube 7. The manifold 11 is made of, for example, stainless steel, and is formed in a cylindrical shape with open upper and lower ends. The manifold 11 is provided to support the reaction tube 7 from below. An O-ring (not illustrated) serving as a seal is provided between the manifold 11 and the reaction tube 7. The manifold 11 is supported by a holder (not illustrated), thereby keeping the reaction tube 7 in a vertically installed state. A reaction container is constituted by the reaction tube 7 and the manifold 11.

The process furnace 2 includes the induction target 6, which serves as a heating target to be heated by induction heating, and an inductive coil 12, which serves as an inductive heater, i.e., a magnetic-field generator. The induction target 6 takes the form of a cylinder made of, for example, a conductive heat-resistant material such as carbon, and is provided to surround the boat 3 accommodated within the reaction chamber 8, i.e., to surround an accommodation region for the wafers 4. The induction target 6 may be formed in a cylindrical shape with open upper and lower ends, or may be formed in a cylindrical shape with a closed upper end and an open lower end. The inductive coil 12 is supported by a coil support 12a made of an insulating heat-resistant material and is provided to surround an outer periphery of the reaction tube 7. The inductive coil 12 is configured to receive alternating current (AC) power from an AC power supply 13, for example, at a frequency of 10 to 450 kHz and a power level of 10 to 200 kW. By an AC magnetic field generated when an alternating current flows through the inductive coil 12, an induction current, i.e., an eddy current flows through the induction target 6, causing the induction target 6 to generate heat due to Joule's heat. With the heat generation of the induction target 6, the wafers 4 held in the boat 3 are heated to a predetermined processing temperature, for example, 1500 to 2000 degrees C., due to a radiant heat from the induction target 6. In addition, to prevent a thermal damage, it is desirable to maintain the temperature of components below the process furnace 2, for example, at 200 degrees C. or lower.

A thermal insulator 14 made of, for example, low-dielectric carbon felt is provided between the reaction tube 7 and the induction target 6. The thermal insulator 14 is formed in a cylindrical shape with a closed upper end and an open lower end. Providing the thermal insulator 14 may prevent the transfer of heat from the induction target 6 to the reaction tube 7 or the outside of the reaction tube 7.

Further, a temperature measurement assembly 15 configured to detect a processing temperature is provided between the boat 3 holding the wafers 4 as described above and the induction target 6. The temperature measurement assembly 15 extends vertically through the manifold 11 to protrude upward from the upper end of the boat 3. The temperature measurement assembly 15 is electrically connected to a temperature controller (not illustrated). The temperature controller regulates a state of supplying electric power from the AC power supply 13 to the inductive coil 12 based on temperature information detected by the temperature measurement assembly 15, thereby controlling the processing temperature for the wafers 4 to be a desired temperature. A heater according to the embodiments is primarily constituted by the induction target 6, the inductive coil 12, the AC power supply 13, and the temperature measurement assembly 15.

Further, an outer thermal-insulation wall 16 is provided outside the inductive coil 12 to surround the reaction chamber 8. The outer thermal-insulation wall 16 is formed with, for example, a water-cooled structure to prevent the transfer of heat from the reaction chamber 8 to the outside. Further, a magnetic shield 17 is provided outside the outer thermal-insulation wall 16 to prevent a leakage of a magnetic field generated by the inductive coil 12 to the outside. The outer thermal-insulation wall 16 and the magnetic shield 17 may be constituted as an integrated structure.

A first gas nozzle 18 including a first gas supply port 18a, and the like are disposed in the process furnace 2. The first gas nozzle 18 is located inside the induction target 6 and is vertically oriented between an accommodation region for the wafers 4 and the induction target 6. The first gas nozzle 18 is made of, for example, a heat-resistant material such as carbon graphite. The first gas supply port 18a is provided at an upper end (tip) of the first gas nozzle 18. A downstream end of a first gas supply pipe 19 is connected to an upstream end of the first gas nozzle 18. The first gas supply pipe 19 is provided to pass through the manifold 11. A gas supplier 21 is connected to an upstream end of the first gas supply pipe 19.

A second gas supply pipe 22 is vertically arranged outside the induction target 6 and between the thermal insulator 14 and the reaction tube 7. A second gas supply port 23 is provided at a downstream end of the second gas supply pipe 22. The second gas supply pipe 22 is provided to pass through the manifold 11. The gas supplier 21 is connected to an upstream end of the second gas supply pipe 22.

A first exhaust port 24 is opened at a sidewall of the manifold 11 facing the first gas supply port 18a at the lateral side of and below the boat insulator 5, i.e., the accommodation region for the wafers 4. Further, a second exhaust port 25 is opened, between the thermal insulator 14 and the reaction tube 7, at a construction wall of the manifold 11 on which the reaction tube 7 is mounted. Branched upstream ends of an exhaust pipe 26 are connected to the first exhaust port 24 and the second exhaust port 25, respectively. The exhaust pipe 26 is provided with a pressure sensor 27 serving as a pressure detector, an auto pressure controller (APC) valve 28 serving as a pressure regulator, and a vacuum pump 29 serving as a vacuum exhauster in this order from the upstream side. The pressure sensor 27, APC valve 28, and vacuum pump 29 are electrically connected to a pressure controller (not illustrated). The pressure controller feedback-controls an opening state of the APC valve 28 based on pressure information measured by the pressure sensor 27, thereby controlling an internal pressure of the reaction chamber 8 to reach a predetermined pressure at a predetermined timing.

By providing the first exhaust port 24 as described above, a gas supplied from the first gas supply port 18a into the reaction chamber 8, i.e., a process gas, flows downward in the reaction chamber 8, i.e., inside the induction target 6 through a region where the boat insulator 5 is provided, and is then discharged via the first exhaust port 24. At this time, the entirety of the wafers 4 are efficiently and uniformly exposed to the gas.

Further, by providing the second exhaust port 25 as described above, an inert gas such as nitrogen supplied from the second gas supply port 23 into the reaction chamber 8 acts as a purge gas, flows between the reaction tube 7 and the thermal insulator 14 and is then discharged from the second exhaust port 25. This prevents the process gas from entering a space between the reaction tube 7 and the thermal insulator 14, preventing adhesion of unwanted products and others to surfaces thereof.

Further, the boat 3 is configured to be capable of being loaded into the reaction chamber 8 (i.e., boat loading) and unloaded from the reaction chamber 8 (i.e., boat unloading) by an elevator (not illustrated). When the boat 3 is loaded into the reaction chamber 8, an opening of the process furnace 2, i.e., a furnace opening, is airtightly closed by a sealing cap 31 via a seal such as an O-ring. In addition, a boat rotator 30 configured to support the boat insulator 5 passes through a center of the sealing cap 31, such that the boat 3 is rotatable by the boat rotator 30.

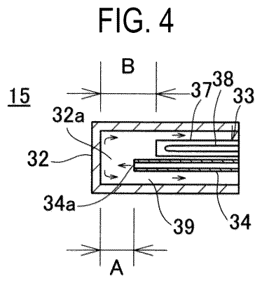

Next, details of the temperature measurement assembly 15 will be described with reference to FIGS. 2 to 4. In addition, the temperature measurement assembly 15 is erected vertically inside the reaction tube 7, but is illustrated as extending horizontally in FIGS. 2 and 4.

The temperature measurement assembly 15 includes a protective tube 32, a sheathed thermocouple 33 serving as a temperature sensor inserted into the protective tube 32, a gas supply pipe 34, a discharge pipe 35, and a seal 36 configured to seal the protective tube 32. In addition, the sheathed thermocouple 33 may be positioned farther from an axis (central axis) of the protective tube 32 than the gas supply pipe 34.

The protective tube 32 is formed in a cylindrical shape with a closed upper end and an open lower end. A material of the protective tube is appropriately selected from various high-temperature ceramics and metals, including oxides such as graphite, Al₂O₃, and MgO, carbides such as TaC, TiC, and SiC, and nitrides such as BN and AlN, depending on conditions such as processing temperature.

The sheathed thermocouple 33 is inserted into the protective tube 32 parallel to the axis of the protective tube 32, so as to pass through the seal 36. The sheathed thermocouple 33 includes a sheath tube 37 and a thermocouple (TC) 38 serving as a temperature measurement gauge arranged inside the sheath tube 37. The sheath tube 37 is formed in a cylindrical shape with a closed upper end and an open lower end. The sheath tube 37 is made of a metal such as Ta or Mo. Further, the sheath tube 37 is filled with, for example, an insulating powder such as magnesium oxide, and is thus configured to prevent the thermocouple 38 disposed therein from moving easily. Further, the sheath tube 37 is filled with an inert gas, and a thermocouple cable extraction hole of the sheath tube 37 is sealed with glass or the like, such that the interior of the sheath tube 37 is sealed in a state that the interior is completely purged with the inert gas.

The gas supply pipe 34 is inserted into the protective tube 32 parallel to the axis of the protective tube 32 so as to pass through the seal 36, thus extending and protruding to the vicinity of an inner wall upper end (tip) of the protective tube 32. Therefore, a space (inner space) 32a with a predetermined size is formed between an upper end of the gas supply pipe 34 and the inner wall upper end of the protective tube 32. Further, the gas supply pipe 34 includes a flow path formed therein and an outlet 34a formed at the tip, and is configured to be capable of supplying an inert gas such as argon gas (Ar gas) or nitrogen gas (N₂ gas) upward into a space 32a inside the protective tube 32 via the outlet 34a. In other words, the space 32a is formed at an upper side inside the gas supply pipe 34, i.e., toward a gas ejection direction. The space 32a is provided to enable the inert gas discharged from the outlet 34a to change a flow direction thereof downward as smoothly as possible, and no solid object is disposed in that space.

In addition, as illustrated in FIG. 4, the upper end (tip) of the gas supply pipe 34 extends and protrudes upward beyond an upper end (tip) of the sheathed thermocouple 33, and a lower end of the gas supply pipe 34 is connected to an inert gas supply apparatus (not illustrated). A dimension A from the upper end of the gas supply pipe 34 to the inner wall upper end of the protective tube 32 is shorter than a dimension B from the upper end of the sheathed thermocouple 33 to the inner wall upper end of the protective tube 32. Therefore, the sheathed thermocouple 33 and the gas supply pipe 34 are arranged respectively such that the upper end of the gas supply pipe 34 is positioned higher than the upper end of the sheathed thermocouple 33. This ensures that the discharged inert gas does not directly come into contact with the sheathed thermocouple 33, but is thermally equalized with the protective tube 32 while flowing along an inner wall of the protective tube 32, and then comes into contact with the sheathed thermocouple 33.

The discharge pipe 35 is inserted into the protective tube 32 parallel to the axis of the protective tube 32, so as to pass through the seal 36. An upper end (tip) of the discharge pipe 35 is positioned near the seal 36 and is configured to be capable of discharging the gas from the inside of the protective tube 32. In other words, the discharge pipe 35, which provides fluid communication between an atmosphere inside the protective tube 32 and an external atmosphere, is open near the seal 36 in a lower region of the protective tube 32. Further, a diameter of the discharge pipe 35 is larger than a diameter of the gas supply pipe 34. This may prevent an increase in the internal pressure of the protective tube 32.

The seal 36 is made of, for example, a heat-resistant adhesive or a heat-resistant resin, and is constituted as a seal that airtightly seals an opening, i.e., the lower end of the protective tube 32. The seal 36 isolates the atmosphere inside the protective tube 32, excluding the discharge pipe 35, from the external atmosphere.

The inert gas supplied to the gas supply pipe 34 is ejected from the outlet 34a to the space 32a inside the protective tube 32, is deflected along the inner wall upper end of the protective tube 32 to descend through a gap 39 between an outer wall of the sheathed thermocouple 33 and the inner wall of the protective tube 32, and is then discharged to the outside via the discharge pipe 35.

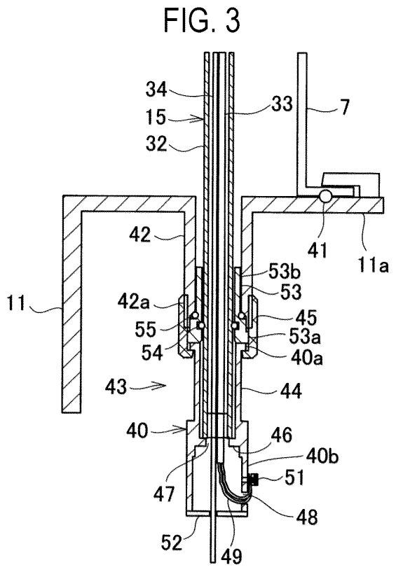

FIG. 3 illustrates an enlarged cross-sectional view illustrating the vicinity of an installation region of the temperature measurement assembly 15. The manifold 11 includes an annular flange 11a formed at the upper end to expand outward in the circumferential direction, and the reaction tube 7 is mounted on the flange 11a. An O-ring 41 is provided between the reaction tube 7 and the flange 11a. The O-ring 41 ensures airtightness between the reaction tube 7 and the flange 11a.

Further, a TC port 42 is formed in the flange 11a. The TC port 42 is formed in a cylindrical shape in which the TC port 42 extends and protrudes downward parallel to the axis of the reaction tube 7, and a threaded portion 42a is formed at the lower end of the TC port 42.

The temperature measurement assembly 15 is held by a TC holder 43. The TC holder 43 includes a casing 40, a cable extraction hole 48 serving as an exhauster, a terminal screw 51, and a sleeve 53 serving as a vacuum joint.

The casing 40 is formed in a substantially cylindrical shape, with an inner diameter larger than an outer diameter of the protective tube 32. A cylindrical recess 44 is formed in the middle of an outer periphery of the casing 40, and a cap nut 45 is loosely fitted into the recess 44 in a non-removable manner. The cap nut 45 is slidable vertically between upper and lower ends of the recess 44. Further, an annular flange 40a is formed at the upper end of the recess 44 to extend and protrude toward an outer peripheral side.

Inside the casing 40, an inner flange 46 is formed, and the inner flange 46 serves as a bonder extending and protruding toward a central side of the casing 40. The inner flange 46 provides a hole 47 smaller than an inner diameter of the casing 40. A diameter of the hole 47 is larger than the inner diameter of the protective tube 32 but is smaller than the outer diameter of the protective tube 32. Therefore, when the casing 40 holds the temperature measurement assembly 15, a lower surface of the protective tube 32 comes into contact with an upper surface of the inner flange 46. In addition, the protective tube 32 and the inner flange 46 are bonded with an adhesive, which integrates the protective tube 32 and the casing 40. Further, the sheathed thermocouple 33, gas supply pipe 34, and discharge pipe 35, which pass through the seal 36, extend and protrude downward through the hole 47.

A cable extraction hole 48 is formed at a peripheral wall of the casing 40 below the inner flange 46. As a wire of the temperature sensor, a thermocouple cable 49 extends and protrudes from a lower end of the sheathed thermocouple 33 and is drawn out of the casing 40 through the cable extraction hole 48. Further, the cable extraction hole 48 also functions as a discharge port configured to discharge the inert gas discharged from the discharge pipe 35 to the outside.

At the outer wall of the casing 40, a flat surface portion 40b parallel to the longitudinal direction of the protective tube 32 is formed, and the terminal screw 51 is provided at the flat surface portion 40b. Providing the terminal screw 51 at the flat surface portion 40b makes it easier to attach or detach the terminal screw 51. The terminal screw 51 functions as an exposed terminal electrically connected to the sheathed thermocouple 33. An end of the thermocouple cable 49 extending and protruding from the cable extraction hole 48 is detachably attached to the terminal screw 51. Further, a gauge (not illustrated) capable of receiving electrical signals from the thermocouple 38 is connectable to the terminal screw 51 via a cable (not illustrated). The cable connected to the terminal screw 51 and the gauge functions as a connector electrically connected to the sheathed thermocouple 33.

A lower end opening of the casing 40 is closed by a holder cap 52 serving as a lid. In addition, a hole for the passage of the gas supply pipe 34 is formed at the holder cap 52, and the holder cap 52 closes the casing 40 with the gas supply pipe 34 passing therethrough. Therefore, the holder cap 52 also functions as a support configured to support a load in a direction perpendicular to an axial direction of the gas supply pipe 34. Further, one end of the discharge pipe 35 passing through the seal 36 is open into the casing 40 below the inner flange 46, allowing fluid communication therebetween. Further, the interior of the casing 40 is purged with the inert gas discharged from the protective tube 32 via the discharge pipe 35. The inert gas that purged the interior of the casing 40 is discharged via the cable extraction hole 48.

The cylindrical sleeve 53 is provided at an upper side of the casing 40. The protective tube 32 is inserted through the sleeve 53, with the lower end of the protective tube 32 in contact with an upper end of the casing 40. Further, the sleeve 53 includes a large-diameter portion 53a and a small-diameter portion 53b with a smaller diameter than the large-diameter portion 53a. An outer diameter of the large-diameter portion 53a is larger than an inner diameter of the TC port 42 but is smaller than an outer diameter of the TC port 42. An outer diameter of the small-diameter portion 53b is smaller than the inner diameter of the TC port 42, allowing the small-diameter portion 53b to be inserted into the TC port 42. Further, an O-ring 54, serving as a first airtight seal, is provided along the entire circumference of an inner wall of the large-diameter portion 53a, and an O-ring 55, serving as a second airtight seal, is provided along the entire circumference of an upper end of the large-diameter portion 53a.

When the protective tube 32 is inserted through the sleeve 53, the O-ring 54 is pressed against an outer wall of the protective tube 32, ensuring an airtightness between the sleeve 53 and the protective tube 32. Further, when the small-diameter portion 53b is inserted into the TC port 42, the O-ring 55 is pressed between the large-diameter portion 53a and the lower end of the TC port 42, ensuring an airtightness inside the sleeve 53 and an inside of the TC port 42. Therefore, an airtightness inside the TC port 42, i.e., the reaction chamber 8, is ensured by the O-rings 54 and 55, which prevents leakage of an atmosphere in the reaction chamber 8 through the TC port 42.

When attaching the temperature measurement assembly 15 to the process furnace 2, the temperature measurement assembly 15 is held by the casing 40 and the protective tube 32 is inserted into the sleeve 53. In this state, the protective tube 32 and the small-diameter portion 53b of the sleeve 53 are inserted into the TC port 42 from below. Further, the cap nut 45 is screwed to the threaded portion 42a formed at the outer peripheral wall of the TC port 42. By screwing the cap nut 45, the flange 40a is pulled upward, i.e., closer to the sleeve 53, by the cap nut 45, thereby pressing the sleeve 53, which is in contact with the flange 40a, against the TC port 42. As the sleeve 53 is pressed, an upper surface of the large-diameter portion 53a is pressed against a lower surface of the TC port 42, thereby airtightly closing the TC port 42 via the O-ring 55. The flange 40a and the cap nut 45 function as an engager for engaging with the sleeve 53.

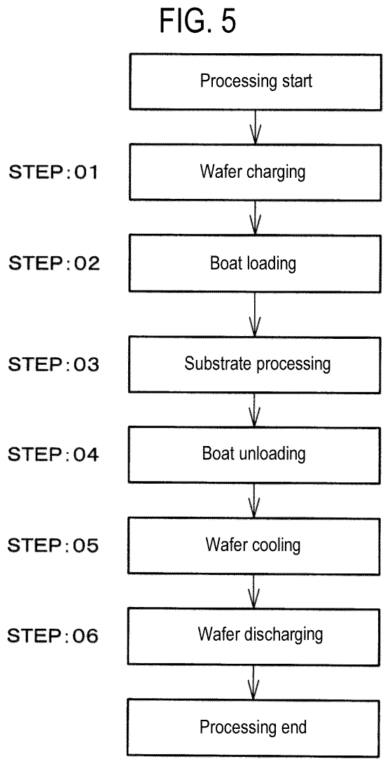

Next, a substrate processing for which the above-described substrate processing apparatus 1 is used will be described with reference to the flowchart in FIG. 5. Herein, an example in which annealing is performed by supplying an argon (Ar) gas, serving as a process gas, into the reaction chamber 8 to remove oxygen from the wafer 4 will be described. In addition, the processing temperature herein refers to a temperature of the wafer 4 or a temperature of the reaction chamber 8, and the processing pressure refers to an internal pressure of the reaction chamber 8. In addition, in the following description, an operation of each component constituting the substrate processing apparatus 1 is controlled by a controller (not illustrated).

The following description begins from a state where the seal cap 31 is lowered by an elevator (not illustrated) and the boat 3 is unloaded from the reaction tube 7 (i.e., boat unloading), such that the wafer 4 does not exist in the boat 3.

### (Wafer Charging and Boat Loading)

When a FOUP accommodating the wafer 4 is introduced into the substrate processing apparatus 1, the wafer 4 is transferred to the boat 3 by a carrier (not illustrated) (STEP: 01). When the boat 3 is charged with a plurality of wafers 4 (i.e., wafer charging), the seal cap 31 is raised by the elevator (not illustrated), and the boat 3 is then loaded inside the induction target 6 within the reaction chamber 8 (i.e., boat loading), and the lower opening of the reaction tube 7 is airtightly closed (sealed) by the seal cap 31 (STEP: 02).

### (Pressure Regulation and Temperature Regulation)

The reaction chamber 8 is vacuum-exhausted, i.e., decompression-exhausted, by the vacuum pump 29. The atmosphere in the reaction chamber 8 flows linearly or substantially linearly through the exhaust pipe 26 and is exhausted via the vacuum pump 29. After the internal pressure of the reaction chamber 8 is vacuum-exhausted, an Ar gas is supplied into the reaction chamber 8. A flow rate of the Ar gas is controlled to be a predetermined flow rate by the gas supplier 21, and is supplied into the reaction chamber 8 via the first gas supply pipe 19 and the first gas nozzle 18 from the tip of the first gas nozzle 18. Further, in parallel with the supply of Ar gas, i.e., in a state where the seal cap 31 closes the opening of the manifold 11, the gas supplier 21 supplies a purge gas whose flow rate is controlled to be a desired flow rate to a space between the reaction tube 7 and the thermal insulator 14 from the second gas supply port 23 via the second gas supply pipe 22. The purge gas is ejected upward, then diffused in the circumferential direction along the ceiling, descends along the circumferential surface, and is then discharged out of the reaction chamber 8 via the second exhaust port 25 and the exhaust pipe 26. The internal pressure of the reaction chamber 8 is measured by the pressure sensor 27, and the APC valve 28 is feedback-controlled based on the measured pressure information to regulate the internal pressure to a predetermined pressure (state of vacuum).

To achieve a predetermined temperature of the wafers 4 in the reaction chamber 8, a predetermined AC power is supplied from the AC power supply 13 to the inductive coil 12, which causes an inductive current to flow through the induction target 6 to raise the temperature, such that the wafers 4 are heated from the periphery thereof by the induction target 6. Induction heating enables efficient heating of the wafers 4. At this time, a state of supplying electric power to the inductive coil 12 is feedback-controlled based on temperature information detected by the sheathed thermocouple 33 to ensure that the entirety of the wafers 4 charged in the boat 3 exhibit a predetermined temperature distribution. In addition, the rotation of the boat 3 and the wafers 4 is initiated by the boat rotator 30.

In addition, in parallel with the supply of electric power to the inductive coil 12, an inert gas is supplied into the protective tube 32 via the gas supply pipe 34. The inert gas is constantly supplied into the protective tube 32 during substrate processing, for example. Alternatively, the supply of the inert gas into the protective tube 32 may be initiated when the temperature detected by the sheathed thermocouple 33 exceeds the ambient temperature.

Supplying the inert gas creates an inert gas atmosphere in the protective tube 32, preventing deterioration of the sheath tube 37 and maintaining the inert gas atmosphere in the sheath tube 37, which prevents oxidation of the sheathed thermocouple 33. Further, by continuously performing the supply of the inert gas from the gas supply pipe 34 and the discharge of the inert gas from the discharge pipe 35, the atmosphere in the protective tube 32 may be constantly replenished with new inert gas, ensuring maintenance of the inert gas atmosphere.

### (Substrate Processing)

The wafer 4 is heated at a predetermined temperature for a predetermined time in an Ar atmosphere. This activates ion-implanted impurities, or removes surface oxygen, resulting in the production of an annealed wafer (STEP: 03).

### (Boat Unloading and Wafer Discharging)

After producing the annealed wafer, the supply of electric power to the inductive coil 12 is cut off, and the wafer 4 is cooled until the temperature thereof drops to a predetermined temperature. After the wafer 4 is cooled, the APC valve 28 is closed to return the internal pressure of the reaction chamber 8 to atmospheric pressure. After that, the seal cap 31 is lowered by the elevator (not illustrated), and the boat 3 is unloaded from the reaction tube 7 (i.e., boat unloading) (STEP: 04).

After the boat 3 is unloaded, i.e., in a state where the seal cap 31 is not closing the opening of the reaction chamber 8, the wafer 4 and the boat insulator 5 are subjected to cooling (STEP: 05).

When the wafer 4 and the boat insulator 5 are cooled to a predetermined temperature, the processed wafer 4 charged in the boat 3 is accommodated in the FOUP by the carrier (not illustrated), and the FOUP is unloaded out of the substrate processing apparatus 1 (STEP: S06), completing the substrate processing.

Processing conditions when the wafer 4 is Ar-annealed are exemplified as follows.
Processing temperature (wafer temperature): 1500 to 1900 degrees C.;
Processing pressure (internal pressure of the process chamber): 1 Pa to atmospheric pressure;
Ar gas: 1 sccm to 5 SLM; and
N₂ gas: 1 sccm to 5 SLM.

By setting each processing condition to a value within each range, film formation may proceed appropriately. In addition, notation of numerical ranges such as “1500 to 1900 degrees C.” as described above refers that both lower and upper limits are included in that range. For example, “1500 to 1900 degrees C.” means “1500 degrees C. or higher and 1900 degrees C. or lower.” The same applies other numerical ranges.

According to the embodiments of the present disclosure, one or more effects as described below are obtained.

In the embodiments, the temperature measurement assembly 15 installed in the reaction chamber 8 includes the protective tube 32, and the sheathed thermocouple 33 and the gas supply pipe 34 inserted into the protective tube 32. Therefore, the inert gas is continuously supplied into the protective tube 32 from the gas supply pipe 34 to continuously replenish the interior of the protective tube 32 with the inert gas, enabling an inert gas atmosphere to be maintained in the protective tube 32. Further, even in a case where oxygen or impurities is volatilized from the protective tube 32 itself, they may be discharged with the constantly supplied inert gas, thereby preventing deterioration of the sheathed thermocouple 33, and prolonging a lifespan of the sheathed thermocouple 33. This enables stable temperature measurement in the reaction chamber 8 for a long time.

In addition, heat movement in the reaction chamber 8 where the temperature is 1500 degrees C. or higher is predominantly governed by heat radiation rather than heat conduction or heat transfer. Therefore, the sheathed thermocouple 33 may maintain responsiveness even in a case where the sheathed thermocouple 33 is not in contact with the protective tube 32.

Further, there is no case where the sheathed thermocouple 33 is directly exposed inside the reaction chamber 8. Thus, even in a case where the sheathed thermocouple 33 deteriorates under a high-temperature environment, metal contamination of the wafer 4 may be prevented.

Further, since the upper end of the gas supply pipe 34 is positioned above the upper end of the sheathed thermocouple 33, the sheathed thermocouple 33 may be in the flow of inert gas from above. This more reliably ensures an inert gas atmosphere around the sheathed thermocouple 33, further prolonging the lifespan of the sheathed thermocouple 33. Further, since the inert gas is made to come into contact with the sheathed thermocouple 33 after being heated to a level equivalent to the temperature of the protective tube 32, the measurement temperature of the sheathed thermocouple 33 is not affected by the inert gas, resulting in improved temperature measurement accuracy.

Further, since the temperature measurement assembly 15 is held by the casing 40 and the seal 36 is not exposed to the outside, it is possible to prevent external forces applied to the seal 36, preventing damage to the seal 36.

Further, the holder cap 52 is configured to close the casing 40 while allowing the gas supply pipe 34 to pass therethrough. In other words, the holder cap 52 is configured to restrict the movement of the gas supply pipe 34 in the circumferential direction. Therefore, even in a case where an external force is applied to the gas supply pipe 34, the holder cap 52 may adsorb the external force, preventing damage to the seal 36.

Further, the protective tube 32 and the casing 40 are bonded with an adhesive, creating an integrated structure. This ensures that the engager engaged with the sleeve 53, i.e., the flange 40a and the cap nut 45 are integrated with connectors, i.e., the thermocouple cable 49 and the terminal screw 51. Thus, damage to the thermocouple cable 49 due to tension is prevented and replacing the thermocouple cable 49 is made easier.

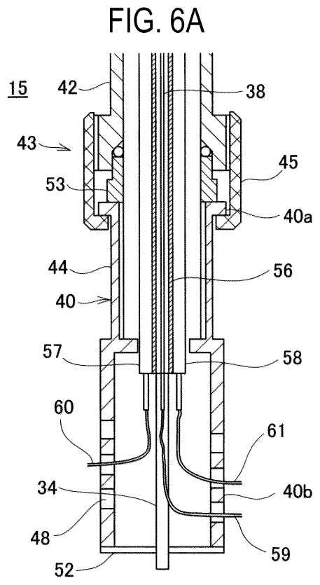

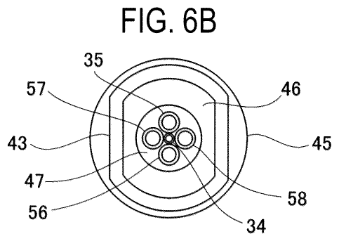

FIGS. 6A and 6B illustrate a modification of the embodiments of the present disclosure. In FIGS. 6A and 6B, components equivalent to those in FIGS. 1 to 4 are given the same reference numerals as FIGS. 6A and 6B, and descriptions thereof are omitted. In the modification, the temperature measurement assembly 15 includes three sheathed thermocouples 56, 57, and 58. The sheathed thermocouples 56, 57, and 58 and the discharge pipe 35 are inserted along the inner wall of the protective tube 32 at equal circumferential intervals, for example, at intervals of 90 degrees as illustrated in FIG. 6B. Further, the gas supply pipe 34 is inserted, for example, along the axis of the protective tube 32, inside the sheathed thermocouples 56, 57, and 58 and the discharge pipe 35. In addition, although not illustrated, similar to the sheathed thermocouple 33, the sheathed thermocouples 56, 57, and 58 each include a sheath tube and a thermocouple as a gauge arranged in the sheath tube.

Further, cable extraction holes 48 are formed at a plurality of locations (six locations in FIG. 6A) in a peripheral wall of the casing 40, and thermocouple cables 59, 60, and 61 of the sheathed thermocouples 56, 57, and 58 are respectively configured to extend and protrude to the outside via any one cable extraction hole 48.

In the modification, the inert gas ejected from the upper end of the gas supply pipe 34 diffuses toward the central side or the outer peripheral side along the inner wall upper end of the protective tube 32, descends along the inner wall of the protective tube 32, passes through the discharge pipe 35, and is then discharged from the cable extraction hole 48 in the same manner as the above-described embodiments.

Also in this modification, the same effects as the above-described embodiments are obtained. Further, by providing the plurality of sheathed thermocouples 56, 57, and 58 along the inner wall of the protective tube 32, it is possible to perform stable temperature measurement regardless of rotated position thereof during installation.

According to the present disclosure in some embodiments, it is possible to achieve stable temperature measurement for a long period under a high-temperature environment.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A temperature measurement assembly comprising:
a gas supply pipe including therein a flow path through which a gas flows;
at least one temperature sensor including a temperature measurement gauge disposed outside the gas supply pipe; and
a protective tube inside which the gas supply pipe and the at least one temperature sensor are disposed,
wherein an outlet of the gas supply pipe configured to eject the gas into the protective tube is positioned higher than the at least one temperature sensor, and the gas descends via a gap between an outer wall of the at least one temperature sensor and an inner wall of the protective tube.

2. The temperature measurement assembly according to claim 1, further comprising a gas discharge pipe configured to discharge the gas from an inside of the protective tube,
wherein a diameter of the gas discharge pipe is larger than a diameter of the gas supply pipe.

3. The temperature measurement assembly according to claim 1, wherein the protective tube includes an internal space in an ejection direction of the gas from the gas supply pipe.

4. The temperature measurement assembly according to claim 1, wherein the at least one temperature sensor includes a sheath tube, and the temperature measurement gauge is disposed inside the sheath tube.

5. The temperature measurement assembly according to claim 1, further comprising a holder including a bonder bonded to a lower side of the protective tube, a connector including an exposed terminal electrically connected to the at least one temperature sensor, and an exhauster configured to exhaust the gas.

6. The temperature measurement assembly according to claim 5, wherein the holder further includes an engager configured to engage with a vacuum joint configured to maintain an airtightness between the holder and the protective tube.

7. The temperature measurement assembly according to claim 4, further comprising a gas discharge pipe configured to discharge the gas from an inside of the protective tube,
wherein the gas supply pipe, the sheath tube, and the gas discharge pipe are arranged to extend inside the protective tube in a longitudinal direction of the protective tube, with each of the gas supply pipe, the sheath tube, and the gas discharge pipe partially exposed outside the protective tube, so that a space between: a lower side of the protective tube; and the gas supply pipe, sheath tube, and gas discharge pipe is sealed with a sealing material.

8. The temperature measurement assembly according to claim 5, wherein the holder includes a casing configured to accommodate a wire of the at least one temperature sensor, and the connector is formed at the casing.

9. The temperature measurement assembly according to claim 8, wherein the casing includes a flat surface portion parallel to a longitudinal direction of the protective tube, and the terminal is disposed on the flat surface portion.

10. The temperature measurement assembly according to claim 8, wherein one end of a gas discharge pipe configured to discharge the gas from an inside of the protective tube is open to enable fluid communication with an interior of the casing, the interior of the casing is purged with the gas, the casing includes a flat surface portion parallel to a longitudinal direction of the protective tube, and the terminal is disposed on the flat surface portion.

11. The temperature measurement assembly according to claim 1, wherein the at least one temperature sensor is positioned farther from a central axis of the protective tube than the gas supply pipe.

12. The temperature measurement assembly according to claim 6, wherein the engager includes a flange configured to come into contact with the vacuum joint and a cap nut configured to be screwed during installation to pull the holder closer to the vacuum joint, and
wherein the cap nut is loosely fitted into the holder by the flange in a non-removable manner.

13. The temperature measurement assembly according to claim 1, wherein a wire of the at least one temperature sensor is drawn out of the casing via a hole provided at the casing and is connected to a terminal screw provided outside the casing.

14. The temperature measurement assembly according to claim 8, further comprising a lid configured to close a lower end opening of the casing and to support the gas supply pipe.

15. The temperature measurement assembly according to claim 4, wherein the at least one temperature sensor includes a plurality of temperature sensors, each individually accommodated in the sheath pipe.

16. A substrate processing apparatus comprising:
a process container;
a heater provided to surround the process container;
a cylindrical heat generator disposed inside the process container to accommodate a substrate, the heat generator capable of being raised in temperature by the heater;
a cylindrical thermal insulator disposed between the process container and the heat generator; and
a temperature measurement assembly disposed inside the heat generator to extend in an axial direction of the heat generator,
wherein the temperature measurement assembly comprises:
a gas supply pipe including therein a flow path through which a gas flows;
at least one temperature sensor including a temperature measurement gauge disposed outside the gas supply pipe; and
a protective tube inside which the gas supply pipe and the at least one temperature sensor are disposed, and
wherein an outlet of the gas supply pipe configured to eject the gas into the protective tube is positioned higher than the at least one temperature sensor, and the gas descends via a gap between an outer wall of the at least one temperature sensor and an inner wall of the protective tube.

17. A method of processing a substrate, comprising:
accommodating a substrate inside a cylindrical heat generator disposed in a process container;
raising a temperature of the cylindrical heat generator by a heater provided to surround the process container; and
controlling the heater based on a temperature measured by a temperature measurement assembly disposed inside the heat generator to extend in an axial direction of the heat generator,
wherein the temperature measurement assembly, which is used in the act of controlling, comprises:
a gas supply pipe including therein a flow path through which a gas flows;
at least one temperature sensor including a temperature measurement gauge disposed outside the gas supply pipe; and
a protective tube inside which the gas supply pipe and the at least one temperature sensor are disposed, and
wherein the gas, which is ejected into the protective tube from an outlet of the gas supply pipe positioned higher than the at least one temperature sensor, descends via a gap between an outer wall of the at least one temperature sensor and an inner wall of the protective tube.

18. A method of manufacturing a semiconductor device comprising the method according to claim 17.
